(19) United States
(12) Patent Application Publication
(10) Pub. No.: US 2025/0079273 A1
(43) Pub. Date: Mar. 6, 2025

(54) BACK SIDE MOLD COMPOUND FLASH SUPRESSION TRENCH FOR EXPOSED DIE PACKAGING

(71) Applicant: Texas Instruments Incorporated, Dallas, TX (US)

(72) Inventors: John Carlo C. Molina, Limay (PH); Connie Esteron, Mabalacat (PH); Cesar Bucasas, Tarlac (PH)

(21) Appl. No.: 18/240,801

(22) Filed: Aug. 31, 2023

(51) Int. Cl. H01L 23/495; H01L 21/56; H01L 23/00; H01L 23/31

(52) U.S. Cl. CPC H01L 23/49575; H01L 21/561; H01L 21/566; H01L 23/3107; H01L 23/4951; H01L 23/49548; H01L 23/49568; H01L 24/05; H01L 24/97; H01L 2224/05022; H01L 2224/05073; H01L 2224/97; H01L 2924/182

(57) ABSTRACT

A back side exposed semiconductor die package with a plurality of leads around a perimeter of the semiconductor die package, a semiconductor die electrically coupled to a plurality of the leads, a plurality of mold compound flash suppression trenches on the back side of the semiconductor die and a back side mold compound free zone are described. The plurality of mold compound flash suppression trenches on the back side of the semiconductor die act as a reservoir to prevent mold compound from encroaching on the mold compound free zone on the back side of the semiconductor die. After formation of the semiconductor die package on the lead frame, individual semiconductor die are singulated, and components such as a head sink may subsequently be attached to the mold compound free zone of the semiconductor die.

### TECHNICAL FIELD

This disclosure relates to the field of semiconductor packages. More particularly, but not exclusively, this disclosure relates to packages with back side exposed semiconductor die.

### BACKGROUND

Packages with back side exposed semiconductor die have emerged as a popular choice for compact high-performance integrated circuit packages. Back side exposed packages provide a convenient method to attach heat sinks to packaged semiconductor die. Packaging solutions such as quad flat no-lead (QFN) packages have emerged as a popular choice for compact and high-performance integrated circuit packaging and may be manufactured with back side exposed semiconductor die. Other packaging solutions which allow for back side exposed semiconductor die are within the scope of this disclosure.

### SUMMARY

A back side exposed semiconductor die package has a plurality of leads around a perimeter of the semiconductor die package, a semiconductor die electrically coupled to a plurality of the leads, and a back side of the semiconductor die which is exposed with a mold compound free zone to allow attachment of a heat sink or other components directly to the semiconductor die. A mold compound, which is electrically insulating, contacts the plurality of leads and the semiconductor die. Trenches on the back side of the semiconductor die prevent mold compound from encroaching on a mold compound free zone on the back side of the semiconductor die.

Trenches on the back side of the semiconductor die may be formed by ablation on the back side of the wafer when the semiconductor die are in wafer form. After singulation of the wafer and attachment of the semiconductor die to a lead frame, a back side exposed microelectronic package may be formed using a mold compound which electrically contacts the plurality of leads and all faces of the semiconductor die except for a mold compound free zone on the back side of the semiconductor die. The trenches on the back side of the semiconductor die act as a reservoir to prevent mold compound from encroaching on the mold compound free zone. After formation of the semiconductor die package on the lead frame, individual semiconductor die are singulated, and components such as a head sink may subsequently be attached to the mold compound free zone of the semiconductor die.

### BRIEF DESCRIPTION OF THE FIGURES

FIG. 1A through FIG. 1O are top views, cross sections, and perspective views of a semiconductor die package having a back side mold compound flash suppression trench, and a back side mold compound free zone depicted in successive stages of an example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor die package has leads around a perimeter of the semiconductor die package. The leads are attached to a lead frame. A semiconductor die containing a plurality of back side mold compound suppression trenches, herein referred to as trenches, is electrically coupled to a plurality of the leads. A mold compound, which is electrically insulating, forms the semiconductor die package contacting the plurality of leads and the semiconductor die. The trenches on the back side of the semiconductor die act as a reservoir to prevent mold compound from encroaching on the mold compound free zone.

After the formation of the semiconductor die package on the lead frame, individual semiconductor die packages are singulated by sawing through the leads. Singulation by sawing enables forming a plurality of semiconductor die packages concurrently using the lead frame, because the mold compound can be formed on all the semiconductor die packages in one operation. After singulation, components such as a head sink may subsequently be attached to the mold compound free zone of the semiconductor die.

It is noted that terms such as top, bottom, over, under, and below may be used in this disclosure. These terms should not be construed as limiting the position or orientation of a structure or element, but should be used to provide spatial relationship between structures or elements.

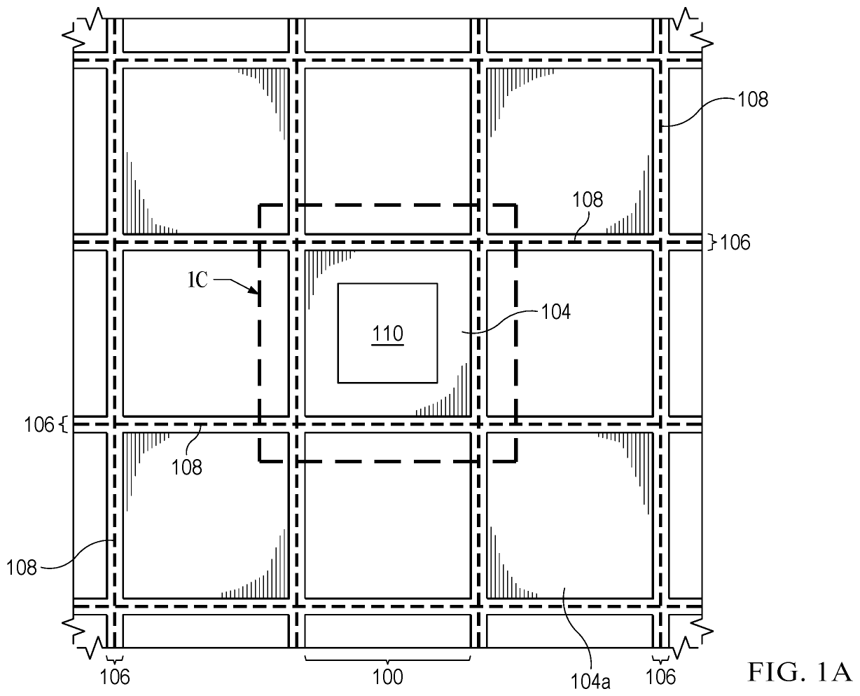

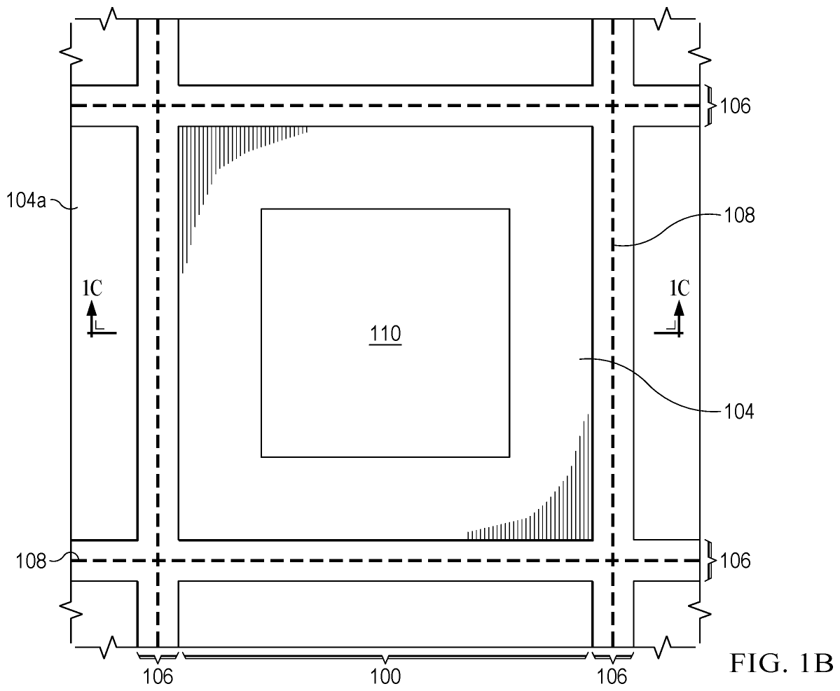

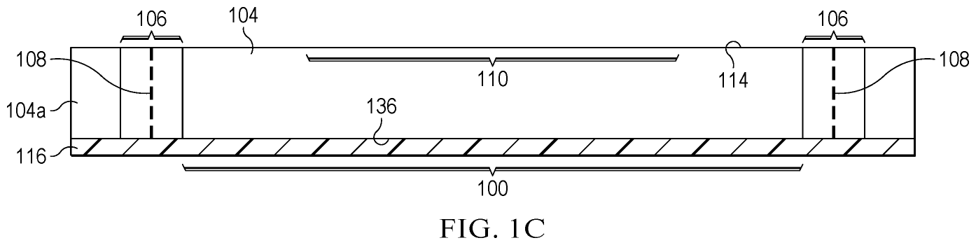

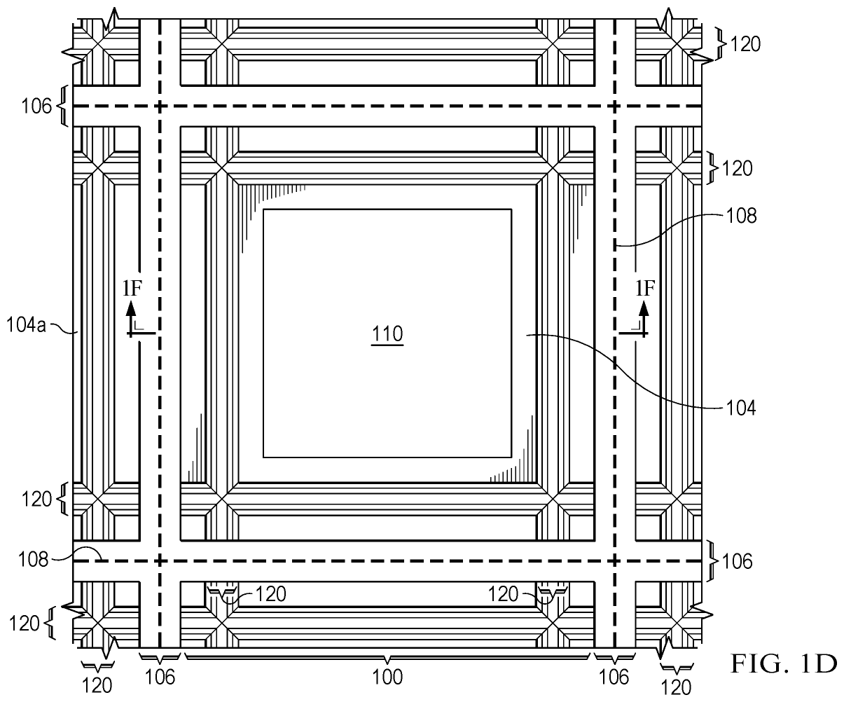

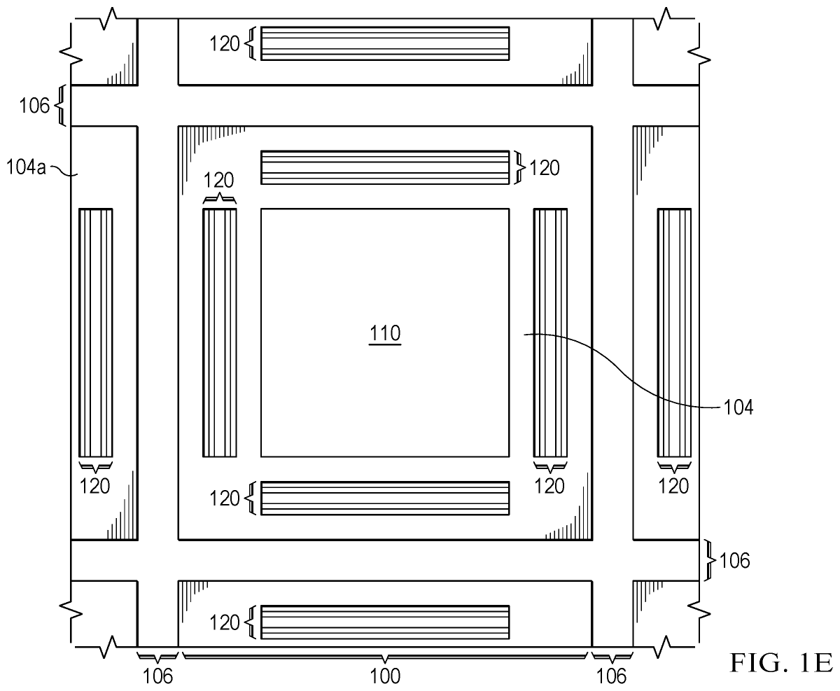

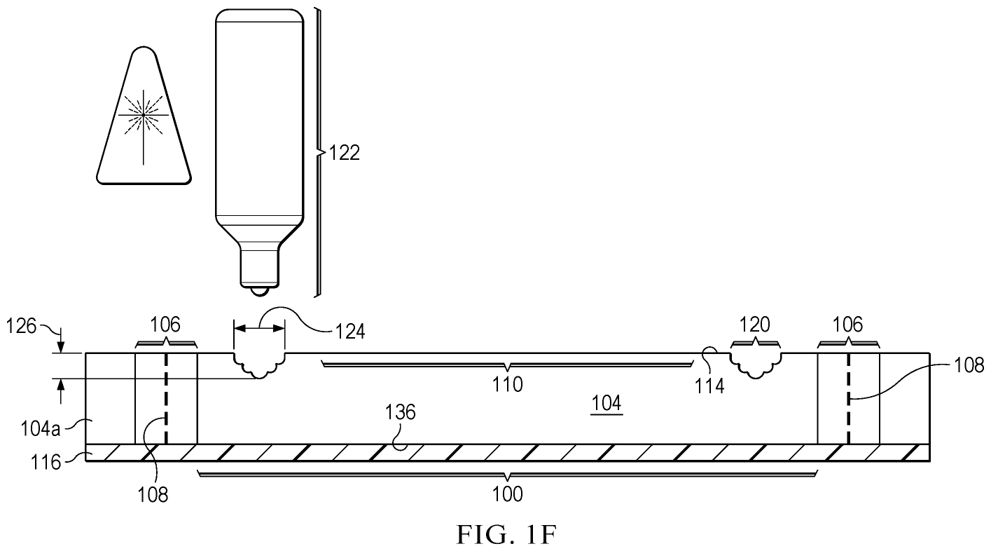

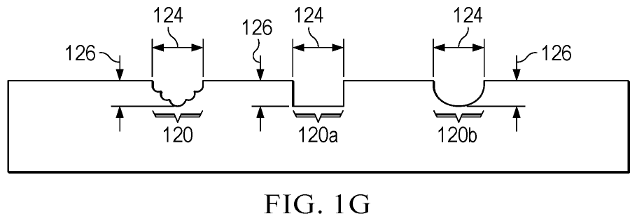

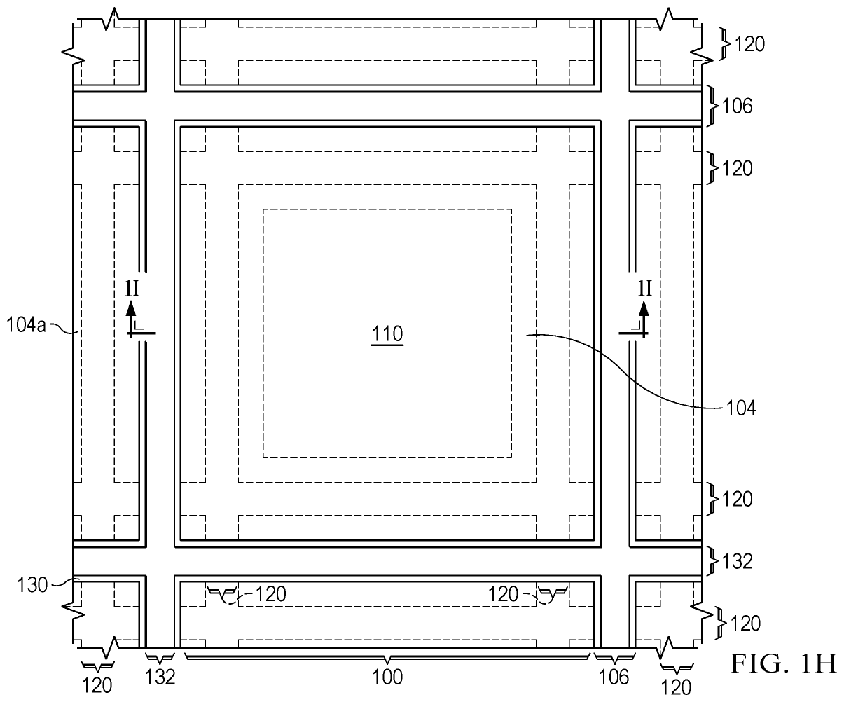

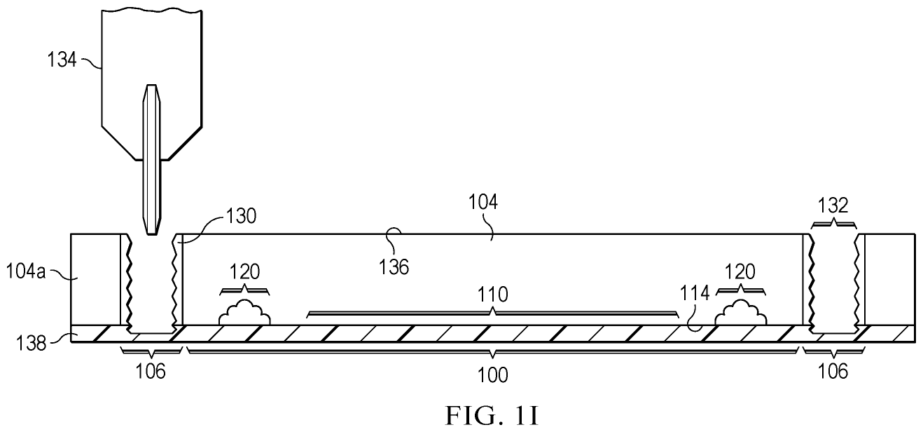

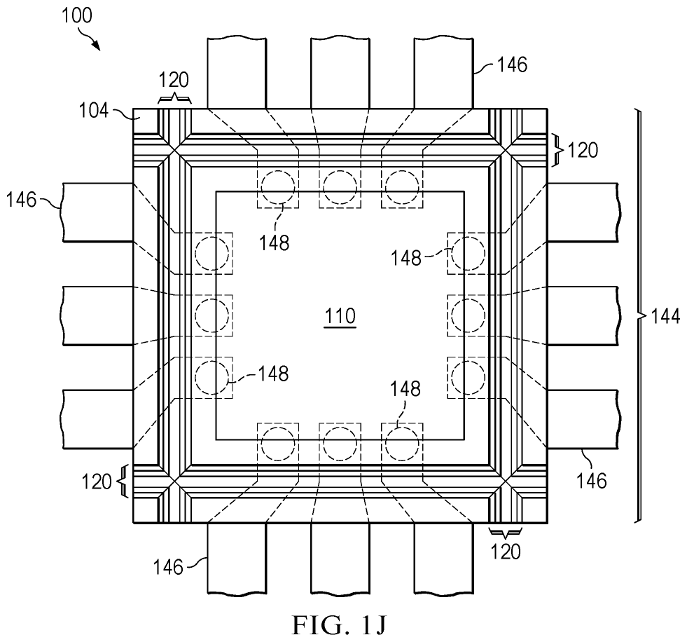

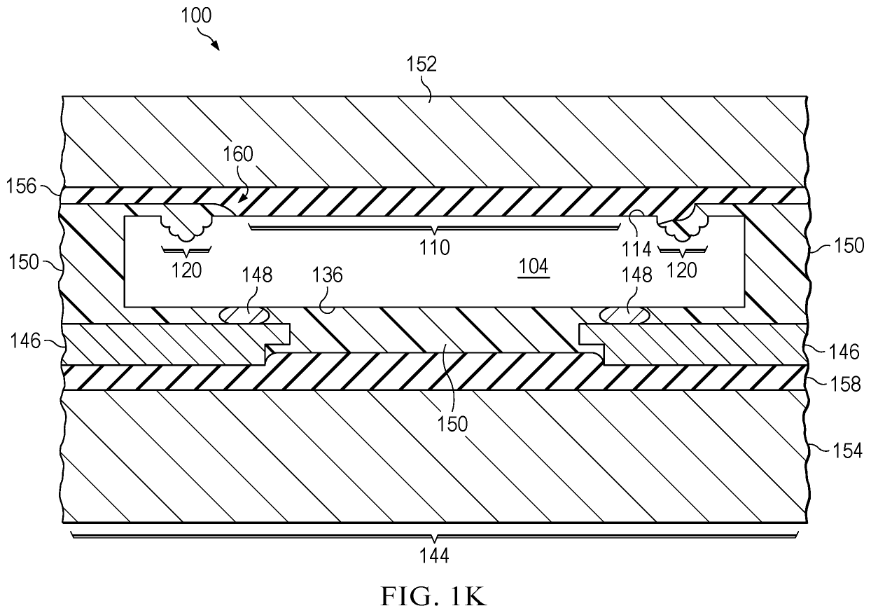

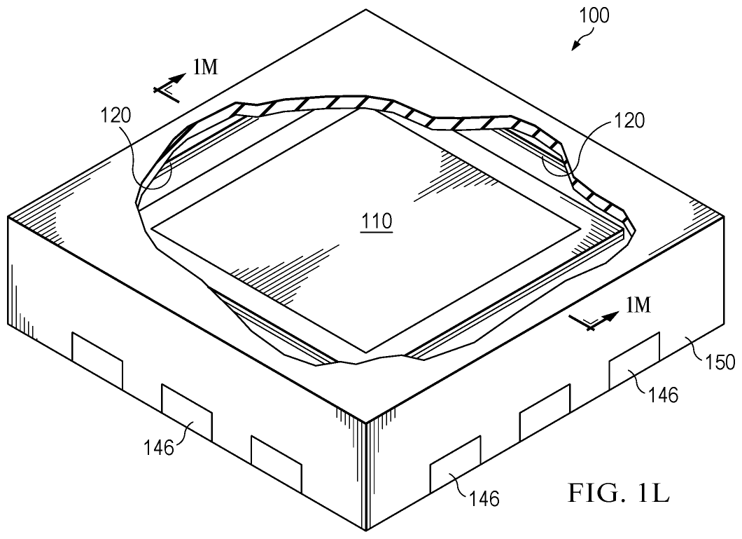

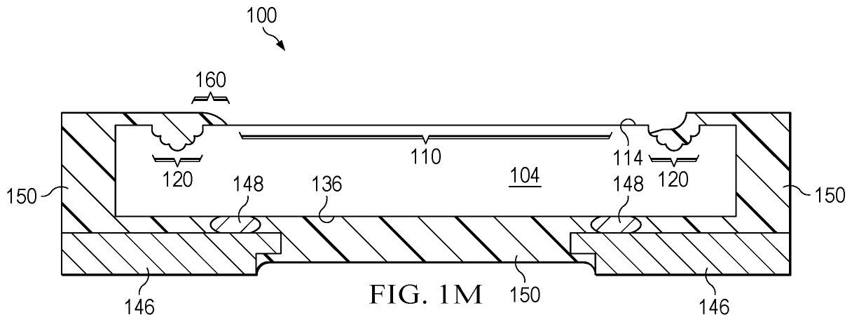

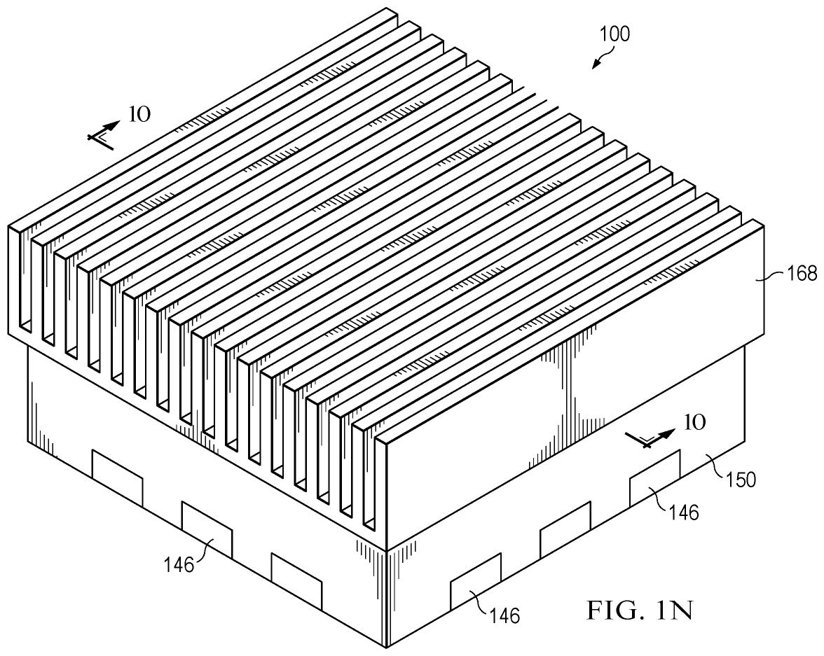

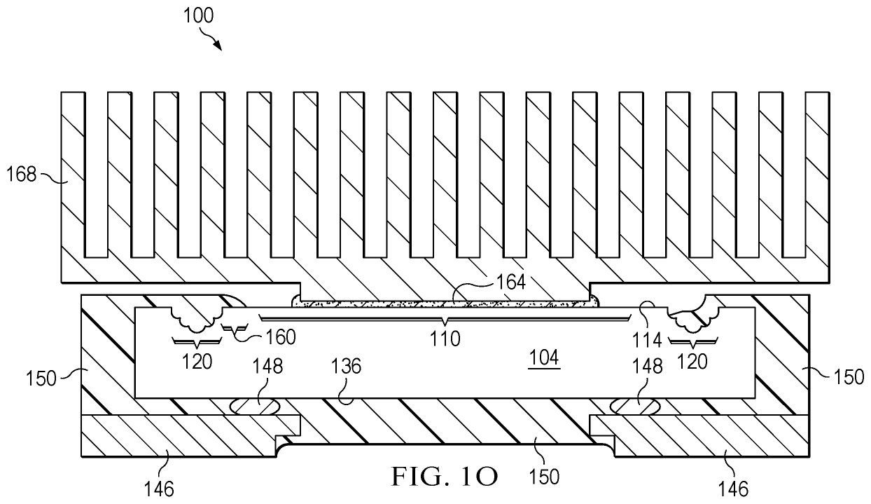

FIG. 1A through FIG. 1O are top views, cross sections, and perspectives of a semiconductor die package having a back side mold compound flash suppression trench, depicted in successive stages of an example method of formation.

Referring to FIG. 1A a top view of a section of a semiconductor wafer, containing a semiconductor die 104 and adjacent semiconductor die 104a is shown. A scribe street 106 exists between the semiconductor die 104 and the adjacent semiconductor die 104a. The saw region 108 in the scribe street 106 indicates the approximate region for sawing between the semiconductor die 104 and adjacent semiconductor die 104a. The scribe street 106 provides space for a saw to saw between the semiconductor die 104 and the adjacent semiconductor die 104a for packaging the semiconductor die 104 and adjacent semiconductor die 104a. The scribe street 106 may also contain features (not specifically shown) such as photolithographic alignment marks and parametric test structures as well as other features necessary for semiconductor wafer manufacturing. The semiconductor die 104 is shown with the back side of the semiconductor wafer facing towards the viewer in FIG. 1A. The back side of the semiconductor wafer includes a mold compound free zone 110. The mold compound free zone 110 is an area on the back side 114 of the semiconductor die 104 (referred to in FIG. 1C) that must remain free of mold compound 150 throughout the packaging process to provide a mold compound free zone 110 for certain types of semiconductor packages, a back side area of the semiconductor package which must be free of mold compound when a heat sink or other component may be subsequently bonded to the back side of the semiconductor die 104 after packaging. The mold compound free zone 110 may be greater than fifty percent of the area of the back side 114 of the semiconductor die 104.

Referring to FIG. 1B, a close-up view of FIG. 1A is shown, focusing on the semiconductor die 104. Adjacent semiconductor die 104a are also shown. Between the semiconductor die 104 and the adjacent semiconductor die 104a is a scribe street 106. In the center of the scribe street 106 is the saw region 108. As in FIG. 1A, the back side of the semiconductor wafer is facing forward. The semiconductor die 104 has the mold compound free zone 110 which remains free of mold compound during the packing process. A cross section of the semiconductor die 104 is shown in FIG. 1C.

Referring to FIG. 1C, a cross section of the semiconductor die 104 of FIG. 1B is shown while the semiconductor die 104 is still in wafer form. A scribe street 106 is between the semiconductor die 104 and the adjacent semiconductor die 104a. In the center of the scribe street 106 is the saw region 108. The semiconductor die 104 has a back side 114 and a device side 136. On the back side 114, is the mold compound free zone 110. The mold compound free zone 110 may be greater than 50% of the area of the back side 114 of the semiconductor die 104 to allow the bonding of components such as heat sinks directly to the back side 114 of the semiconductor die 104. Saw tape 116 is attached to the device side 136 of the semiconductor die 104.

Referring to FIG. 1D, a top-down view of a semiconductor wafer including a semiconductor die 104 and adjacent semiconductor die 104a facing forward is shown. In FIG. 1D, the back side of the semiconductor die 104 is facing the viewer. The top-down view of the semiconductor wafer shown in FIG. 1D is shown at a point in the packaging formation after a back grind operation (not specifically shown) and before a wafer saw operation (referred to in FIG. 1H). After the back grind operation, A plurality of mold compound flash suppression trenches 120 are formed in back side 114 of the semiconductor die 104 between the scribe street 106 and the mold compound free zone 110. The plurality of mold compound flash suppression trenches 120 are also formed in the adjacent semiconductor die 104a. The mold compound flash suppression trenches 120 are formed either by ablating material from the back side of the semiconductor die 104 using a laser or similar technique, or the mold compound flash suppression trenches 120 may be made using a partial sawing method. The mold compound flash suppression trenches 120 have a trench depth 126 and a trench width 124 (referred to in FIG. 1F). The example in FIG. 1D shows a series of mold compound flash suppression trenches 120 perpendicular to each other in which one or more of the plurality of mold compound flash suppression trenches 120 on the back side 114 of the semiconductor die 104 intersect and form a continuous trench region around the mold compound free zone 110. Mold compound flash suppression trenches 120 which are at angles other than perpendicular, and mold compound flash suppression trenches 120 with geometries in which one or more of the plurality of mold compound flash suppression trenches 120 are not continuous around the mold compound free zone 110 and do not intersect as shown in FIG. 1E are also within the scope of the disclosure.

FIG. 1F is a cross section through the semiconductor die 104 of FIG. 1D. The cross section shown in FIG. 1F is shown at a point in the packaging formation after a back grind operation (not specifically shown), after the formation of a mold compound flash suppression trenches 120, and before a wafer saw operation (referred to in FIG. 1H). The device side 136 of the semiconductor die 104 is attached to saw tape 116. The scribe street 106 is between the semiconductor die 104 and the adjacent semiconductor die 104a. The saw region 108 is near the center of the scribe street 106. The mold compound free zone 110 is also shown in the cross-section view of FIG. 1E. The mold compound free zone 110 is located on the back side 114 of the semiconductor die 104. The mold compound free zone 110 is greater than 50% of the area of the back side 114 of the semiconductor die 104 or greater. A mold compound free zone 110 of greater than 50% of the area of the back side 114 of the semiconductor die 104 is advantageous as it provides sufficient area which is free of subsequently formed mold compound 150 (referring to FIG. 1K) to provide a clean surface for subsequent bonding of components such as a heat sink 168 (referring to FIG. N and FIG. 1O) by way of example.

The mold compound flash suppression trenches 120 are formed in back side 114 of the semiconductor die 104 between the scribe street 106 and the outer perimeter of the mold compound free zone 110. The mold compound flash suppression trenches 120 have a trench width 124 and a trench depth 126. The trench width 124 is 0.1 microns or greater. The trench depth 126 is greater than 0.1 microns. The mold compound suppression trenches may be formed using a laser ablation process 122. The trench width 124 and trench depth 126 may be varied by adjusting the laser ablation process 122 laser energy or laser dwell time. Multiple passes through the laser ablation process 122 laser ablation tool may be necessary to achieve the trench width 124 and trench depth 126 desired. The mold compound flash suppression trenches 120 may also be formed by a partial saw process (not specifically shown). The trench depth 126 is less than the thickness of the bulk material of the wafer and does not reach a depth where it intersects with the active semiconductor die 104.

FIG. 1G is a cross sectional view of a scalloped mold compound flash suppression trench 120, a vertical walled mold compound flash suppression trench 120a, and a U-shaped mold compound flash suppression trench 120b. Other cross-sectional geometries of mold compound flash suppression trenches are within the scope of the disclosure. The scalloped mold compound flash suppression trench 120 has a trench width 124 and a trench depth 126. The scalloped mold compound flash suppression trench 120 profile may be formed by multiple passes using an ablation process to form the scalloped mold compound flash suppression trench 120. The vertical walled mold compound flash suppression trench 120a has a vertical sidewall and flat bottom with a trench width 124 and a trench depth 126. The vertical walled mold compound flash suppression trench 120a profile may be formed when a sawing process is used to form vertical walled mold compound flash suppression trench 120a. The U-shaped mold compound flash suppression trench 120b has a U-shaped profile. The U-shaped mold compound flash suppression trench 120b profile may be formed if a single pass ablation method is used to form the U-shaped mold compound flash suppression trench 120b.

FIG. 1H is a top-down view of the semiconductor die 104 and adjacent semiconductor die 104a after wafer singulation and FIG. 1I is a cross section of the semiconductor die 104 and adjacent semiconductor die 104a of FIG. 1H after singulation. Referring to FIG. 1H and FIG. 1I, a semiconductor wafer is initially mounted onto saw tape 116. The semiconductor die 104 is singulated from the adjacent semiconductor die 104a by a singulation sawing process using a singulation saw blade 134. The singulation sawing process cuts through the scribe street 106, and separates, the semiconductor die 104 from adjacent semiconductor die 104a. After sawing, a scribe street sawn region 132 and a residual scribe street 130 remains between the semiconductor die 104 from adjacent semiconductor die 104a. After the sawing of the wafer, the semiconductor die 104 and adjacent semiconductor die 104a may be removed from the saw tape 116 and bonded to a lead frame 144 as discussed in FIG. 1J and FIG. 1K. While the example in FIGS. 1H and 1I are for singulation by sawing, other methods of singulation are within the scope of the disclosure.

FIG. 1J is a top view of the semiconductor package 100 and FIG. 1K is a cross section of the semiconductor package 100 of FIG. 1J after the semiconductor die 104 is sawn from the semiconductor wafer and mounted on a lead frame 144. The lead frame 144 may contain adjacent semiconductor packages (not specifically shown). The semiconductor package 100 includes a plurality of leads 146 as part of the lead frame 144.

As shown in FIG. 1K, device side 136 of the semiconductor die 104 is attached to the plurality of leads 146 of the lead frame 144 through a conducting die to lead frame bonding material 148. Mold compound 150 is formed on the lead frame 144 including contacting portions of the plurality of leads 146, the semiconductor die 104, and on the conducting die to lead frame bonding material 148. The mold compound 150 in this example is formed between a bottom mold plate 154 and a top mold plate 152. In this example, a top compressible mold release film 156 is located between the top mold plate 152 and the bottom surface of the semiconductor die 104. A bottom compressible mold release film 158 is located between the bottom mold plate 154 and bottom surfaces of the plurality of leads 146. The mold compound 150 is electrically insulating. The top compressible mold release film 156 between the back side 114 of the semiconductor die 104 and the top mold plate 152 may not provide a seal sufficient to prevent mold compound 150 from leaking on to the back side 114 of the semiconductor die 104. It is advantageous to add mold compound flash suppression trenches 120 to the back side 114 of the semiconductor die 104 to prevent mold compound 150 from impinging on the mold compound free zone 110. The mold compound flash suppression trenches 120 on the back side 114 of the semiconductor die 104 as shown in FIG. 1J create a continuous trench between the outer perimeter of the semiconductor die 104 and the mold compound free zone 110. Mold compound flash suppression trenches 120 which do not intersect each other (as shown in FIG. 1E) are also within the scope of the disclosure. As shown in FIG. 1K, after the mold compound has been formed between the top mold plate 152 and the bottom mold plate 154, the mold compound flash suppression trenches 120 advantageously provides a reservoir for any mold compound 150 which may extend past the outer perimeter of the semiconductor die 104 toward the mold compound free zone 110 between the top compressible mold release film 156 and the back side 114 of the semiconductor die 104. While the mold compound flash suppression trenches 120 may fill with mold compound 150 in some regions and residual mold compound 160 may extend past the mold compound flash suppression trenches 120 in some areas, the void volume of the mold compound flash suppression trenches 120 prevents the residual mold compound 160 from impinging into the mold compound free zone 110. After the semiconductor package 100 is formed, the semiconductor package 100 is singulated from adjacent semiconductor packages 100 (not specifically shown).

FIG. 1L is a perspective view of the semiconductor package 100 including mold compound flash suppression trenches 120 after singulation. The semiconductor package 100 illustrated in FIG. 1L is a quad flat no-lead (QFN) package with the back side 114 of the semiconductor die 104 exposed. FIG. 1M is a cross sectional view of the semiconductor package 100 shown in FIG. 1L. After singulation, referring to FIG. 1L and FIG. 1M, the mold compound free zone 110 on the back side 114 of the semiconductor die 104 is free of mold compound 150. While the mold compound free zone 110 is free of mold compound 150, in some areas, the mold compound flash suppression trenches 120 may fill with mold compound 150 and residual mold compound 160 may exist on the back side 114 of the semiconductor die 104 between the mold compound free zone 110 and the mold compound flash suppression trenches 120. The mold compound flash suppression trenches 120 keep the mold compound free zone 110 completely free of mold compound 150 allowing subsequent bonding of heat sinks or other elements directly to the back side 114 of the semiconductor die 104. Other regions of the mold compound flash suppression trenches 120, are not completely filled with mold compound 150. The lead frame 144 is connected to the device side 136 of the semiconductor die 104 through the die to lead frame bonding material 148.

Referring to FIG. 1N and FIG. 1O, FIG. 1N shows a perspective view of the semiconductor package 100 shown in FIG. 1L and FIG. 1M and after a heat sink 168 has been attached to the semiconductor package 100. FIG. 1N shows the heat sink on top of the semiconductor die 104. The mold compound free zone is under the heat sink 168 and not visible in the perspective view shown in FIG. 1N. FIG. 1O is a cross sectional view of the semiconductor package 100 shown in FIG. 1N. Referring to FIG. 1O the heat sink 168 is attached to the back side 114 of the semiconductor die 104 with a heat sink attach material 164 such as a thermal grease or a filled adhesive by way of example. The heat sink attach material 164 is within the mold compound free zone 110. Attaching the heat sink 168 to the back side 114 of the semiconductor die 104 in the mold compound free zone 110 which is free of mold compound 150 provides a clean surface, free of mold compound 150, for reliable bonding of the heat sink 168 to the semiconductor die 104.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A semiconductor package, comprising:
a plurality of leads around a perimeter of the semiconductor package;
a semiconductor die electrically coupled to the plurality of leads, the semiconductor die including a device side and a back side;
a plurality of trenches on a back side of the semiconductor die;
a mold compound contacting portions of the plurality of leads and the semiconductor die, and
a mold compound free zone on the back side of the semiconductor die between the plurality of trenches which is free of the mold compound.

2. The semiconductor package of claim 1, wherein one or more of the plurality of trenches on the back side of the semiconductor die intersects another of the plurality of trenches.

3. The semiconductor package of claim 1, wherein one or more of the plurality of trenches on the back side of the semiconductor die does not intersect another of the plurality of trenches.

4. The semiconductor package of claim 1, wherein the mold compound free zone on the back side of the semiconductor die is greater than fifty percent of an area of the back side of the semiconductor die.

5. The semiconductor package of claim 1, wherein a depth of the plurality of trenches on the back side of the semiconductor die is greater than 0.1 microns.

6. The semiconductor package of claim 1, wherein a width of the plurality of trenches on the back side of the semiconductor die is greater than 0.1 microns.

7. The semiconductor package of claim 1, wherein one or more of the plurality of trenches on the back side of the semiconductor die is perpendicular to an adjacent trench.

8. The semiconductor package of claim 1, wherein the mold compound extends past one or more of the plurality of trenches on the back side of the semiconductor die, but does not extend into the mold compound free zone.

9. The semiconductor package of claim 1, wherein the plurality of trenches are between an outer perimeter of the semiconductor die and an outer perimeter of the mold compound free zone.

10. The semiconductor package of claim 1, further comprising a heat sink attached to the back side of the semiconductor die in the mold compound free zone using a heat sink attach material.

11. A method of forming a semiconductor package, comprising:
forming a plurality of trenches on a back side of a semiconductor wafer;
singulating the semiconductor wafer into a plurality of semiconductor die, each semiconductor die containing one or more of the plurality of trenches;
electrically coupling a semiconductor die to a plurality of leads extending to a perimeter of the semiconductor package; and
forming a mold compound on the plurality of leads and on the semiconductor die, wherein the mold compound does not extend to a mold compound free zone on a back side of the semiconductor die between the plurality of trenches, the mold compound being electrically insulating.

12. The method of claim 11, wherein one or more of the plurality of trenches is formed by an ablation process.

13. The method of claim 11, wherein one or more of the plurality of trenches is formed using a saw process.

14. The method of claim 11, wherein a depth of the plurality of trenches is greater than 0.1 microns.

15. The method of claim 11, wherein a width of the plurality of trenches is greater than 0.1 microns.

16. The semiconductor package of claim 11, wherein the plurality of trenches intersects adjacent trenches and form a continuous trench around the mold compound free zone.

17. The method of claim 11, wherein one or more of the plurality of trenches does not intersect another of the plurality of trenches.

18. The method of claim 11, wherein one or more of the plurality of trenches is formed perpendicular to an adjacent trench.

19. The method of claim 11, wherein the mold compound extends past one or more of the plurality of trenches, but does not extend into the mold compound free zone.

20. The semiconductor package of claim 11, wherein the plurality of trenches are formed between an outer perimeter of the semiconductor die and an outer perimeter of the mold compound free zone.
